(19) United States
(12) Patent Application Publication
(10) Pub. No.: US 2003/0041437 A1
(43) Pub. Date: Mar. 6, 2003

(54) System and method for assembling a multisensor device

(76) Inventors: John Derek Williams, New Palestine, IN (US); James E. Walters, Carmel, IN (US)

Correspondence Address: MARGARET A. DOBROWITSKY, DELPHI TECHNOLOGIES, INC., Legal Staff, Mail Code: 480-414-420, P.O. Box 5052, Troy, MI, 48007-5052, US

(21) Appl. No.: 09/944,418

(22) Filed: Aug. 31, 2001

(51) Int. Cl. G01R 3/00; B23P 19/00; H05K 3/30

(52) U.S. Cl. 29/595; 29/834; 29/729; 29/709

(57) ABSTRACT

Method and system for assembling a multisensor device that includes at least two sensors operable to provide a respective stream of pulses indicative of angular information of a rotating object are provided. The sensors are assembled so that the streams of pulses have an accurate phasing relationship relative to one another. The method allows to provide a sensor carrier. The method further allows to locate the sensor carrier to have a predefined spatial relationship relative to a target wheel. The sensor carrier includes a passageway for receiving each of the sensors. The passageway allows slidable movement to selected ones of the sensors along a phasing axis. As relative movement between the target wheel and the sensor carrier occurs, each of the sensors is energized to provide a respective stream of pulses. A determining action allows to determine the phasing relationship of each stream of pulses relative to one another. Based on the determined phasing relationship, the relative positioning of each selected sensor is adjusted along the phasing axis until a desired phasing relationship is achieved between the streams of pulses. Once the desired phasing relationship is achieved, each sensor is affixed in the sensor carrier passageway to ensure the respective stream of pulses provided by the at least two sensors maintain the desired phasing relationship.

### BACKGROUND OF THE INVENTION

The present invention relates generally to the assembling of a multisensor device, and, more particularly, to method and system for assembling a multisensor device including at least two sensors operable to provide a respective stream of pulses indicative of angular information of a rotating object so that the streams of pulses have an accurate phasing relationship relative to one another.

The Hall effect is one well-known example of galvanomagnetic effects that occur when a current-carrying conductor or semiconductor is subject to a magnetic field. Another well-known example of galvanomagnetic effects is the magnetoresistance effect. Presently, commercially available sensing or switching devices capitalize on the Hall or the magnetoresistance effect to provide devices that are responsive to a magnetic field. Such devices, generally employing circuitry in integrated circuit form, control the current and/or voltage in the sensor and provide a respective stream of output pulses, as an incident magnetic field reaches prescribed threshold levels. Such sensors generally exhibit a hysteresis loop so that, for example, once the incident magnetic field reaches the level necessary to turn the sensor to an “on” state, that incident magnetic field will need to be reduced or in some cases reversed to turn the sensor back to an “off” state. The difference between the magnetic field intensity (flux density) at which the sensor turns “on” (also referred to as the operate point), and that at which the sensor turns “off” (the release point) is referred to as the hysteresis of the sensor device. There is a great deal of variability in the operate point, the release point and to a somewhat lesser extent in the hysteresis within production runs of these devices. Thus, it becomes quite difficult to mass-produce devices employing these types of sensors with any consistency. Presorting mass-produced sensors to select those with very closely similar characteristics is a common but expensive practice that has attempted to solve the manufacturing variability peculiar to these devices.

There is a wide range of applications for such sensing devices, including position monitoring and counting applications. For example, the number or fraction of turns of a shaft, shaft angular velocity, or even shaft angular acceleration, may be monitored by positioning a wheel on such a shaft having a magnetized periphery of alternating north and south poles, with one or more Hall effect sensors mounted adjacent to that periphery to change their respective state each time the relatively moving periphery of the wheel changes from a north to a south pole. In this common application, the Hall effect sensor may provide a square wave output as the shaft rotates at a constant speed and subsequent processing of this square wave output provides the desired information about shaft rotation. The greater the number of poles disposed about the periphery of the wheel, the more accurate the sensing of the shaft angular behavior becomes. It will be appreciated, however, that, for a given wheel size, there is an upper bound on the number of poles about its periphery which can be sensed by the Hall effect sensor beyond which bound the Hall effect sensor would fail to sense passage of the poles.

Such an arrangement to monitor the angular behavior of a shaft, such as maintaining a count of the number of turns or fractions of turns executed by the shaft, the angular velocity of the shaft, or the angular acceleration of the shaft, or even sensing a particular angular orientation of that shaft have a wide variety of applications including, by way of example, control of dynamoelectric machines, e.g., induction, and synchronous machines, including permanent magnet, reluctance, Lundell and other types of synchronous machines, fluid or other material metering devices, monitoring or control of machine processes, as well as other applications in which the accurate monitoring of the angular behavior of a rotatable object is desired.

The manufacturing variability of these types of devices, as well as the requirement for precise positioning of such devices relative to such an exemplary rotating target wheel, make it very difficult to achieve an accurate phasing relationship at constant wheel angular velocity since device variations as well as variation in the air gap between the switching device and the wheel periphery could significantly affect differences between the time interval during which the sensor is “on” and the time interval during which the sensor is “off”. For some subsequent signal processing applications, this variability is simply unacceptable.

As propulsion systems and electric machine controls continue to evolve, and various dynamoelectric machine technologies become viable for automotive applications, such as those using flywheel integrated starter/alternator systems for electric or hybrid vehicle propulsion systems, the need for techniques for producing multisensor devices having an accurate phasing relationship becomes evident. In those applications, a relatively high initial torque is desired so that, for example, an internal combustion engine coupled to the starter system can be started as quickly as possible even under extreme environmental conditions.

Traditional design initiatives would possibly suggest focusing on the development of an ASIC (Application Specific Integrated Circuit) device for achieving the required high rotor position sensing accuracy and repeatability. Unfortunately, this approach is believed to be costly and would not necessarily overcome the above-described inherent physical constraints of these devices. Other known technologies have generally depended on the high resolution and accuracy of relatively expensive resolvers or encoders to meet the rotor position requirements of traditional electric or hybrid drives. Thus, either of these approaches is inconsistent with a design that should be low-cost and reliable in order to prevail in the market place relative to competing technologies. The assignee of the present invention has recently developed innovative advances in the field of control of dynamoelectric machines that greatly alleviate the high resolution requirements. See for example U.S. patent application Ser. No. ______ (Attorney Docket DP-304528) that describes one exemplary application based on a low-cost and reliable sensing scheme that allows a standard vector controller that normally operates in a sinusoidal alternating current (AC) mode of operation to run during start up of the machine in a brushless direct current (BLDC) mode of operation to take advantage of the relatively higher torque characteristics that are achievable during the BLDC mode of operation. Once the startup of the machine is achieved, the machine seamlessly transitions from the BLDC mode of operation to the sinusoidal mode of operation.

These advances have enabled relatively low-cost sensing technology to be considered, provided a sufficiently high level in the accuracy of the phasing relationship of the output signals of the multisensor device is provided. As suggested above, the lack of consistent manufacturing techniques for these types of multisensor devices, cumulatively tend to exacerbate the phasing inaccuracies of each sensing element. Thus, it is desirable to provide low-cost techniques that allow for systematically reducing the phasing inaccuracies that presently affect the performance of such multisensor devices.

### BRIEF SUMMARY OF THE INVENTION

Generally, the present invention fulfills the foregoing needs by providing in one aspect thereof, a method for assembling a multisensor device including at least two sensors operable to provide a respective stream of pulses indicative of angular information of a rotating object. The sensors are assembled so that the streams of pulses have an accurate phasing relationship relative to one another. The method allows to provide a sensor carrier. The method further allows to locate the sensor carrier to have a predefined spatial relationship relative to a target wheel. The sensor carrier includes a passageway for receiving each of the sensors. The passageway allows slidable movement to selected ones of the sensors along a phasing axis. As relative movement between the target wheel and the sensor carrier occurs, each of the sensors is energized to provide a respective stream of pulses. A determining action allows to determine the phasing relationship of each stream of pulses relative to one another. Based on the determined phasing relationship, the relative positioning of each selected sensor is adjusted along the phasing axis until a desired phasing relationship is achieved between the streams of pulses. Once the desired phasing relationship is achieved, each sensor is affixed in the sensor carrier passageway to ensure the respective stream of pulses provided by the at least two sensors maintain the desired phasing relationship.

The present invention further fulfills the forgoing needs by providing in another aspect thereof, a system for assembling a multisensor device including at least two sensors operable to provide a respective stream of pulses indicative of angular information of a rotating object. The system includes a sensor carrier. The system further includes a registering plate configured to provide a predefined spatial relationship to the sensor carrier relative to a target wheel. The sensor carrier includes a passageway for receiving each of the sensors. The passageway allows slidable movement to selected ones of the sensors along a phasing axis. A respective module is provided for energizing each of the sensors to provide a respective stream of pulses, as relative movement between the target wheel and the sensor carrier occurs. The system further includes a controller including a phase-determining module configured to determine the phasing relationship of each stream of pulses relative to one another. Based on the determined phasing relationship, a position-adjusting module is configured to adjust the relative positioning of each selected sensor along the phasing axis until a desired phasing relationship is achieved between the streams of pulses. Once the desired phasing relationship is achieved, a sensor-affixing module is configured to affix each sensor in the sensor carrier passageway to ensure the respective stream of pulses provided by the at least two sensors maintain the desired phasing relationship.

### BRIEF DESCRIPTION OF THE DRAWINGS

The features and advantages of the present invention will become apparent from the following detailed description of the invention when read with the accompanying drawings in which:

FIG. 1 illustrates a schematic representation of one exemplary embodiment of a system for assembling a multisensor device including a controller for positioning individual sensor components so that output signals from the device indicative of angular information of a rotating object have an accurate phasing relationship relative to one another.

FIG. 2 illustrates a schematic representation of another exemplary embodiment of a system for assembling the multisensor device.

FIG. 3 illustrates exemplary details regarding the controller of FIG. 1 and including a position-adjusting module.

FIG. 4 illustrates exemplary details regarding the position-adjusting module of FIG. 3.

FIG. 5 illustrates exemplary output signals from the multisensor device that in accordance with aspects of the present invention are adjusted during assembly of the device to have an accurate phasing relationship to one another.

FIG. 6 illustrates a cross-sectional view of an exemplary sensor carrier that may be used for practicing aspects of the present invention.

FIGS. 7 and 8 illustrate details regarding the sensor carrier of FIG. 6.

### DETAILED DESCRIPTION OF THE INVENTION

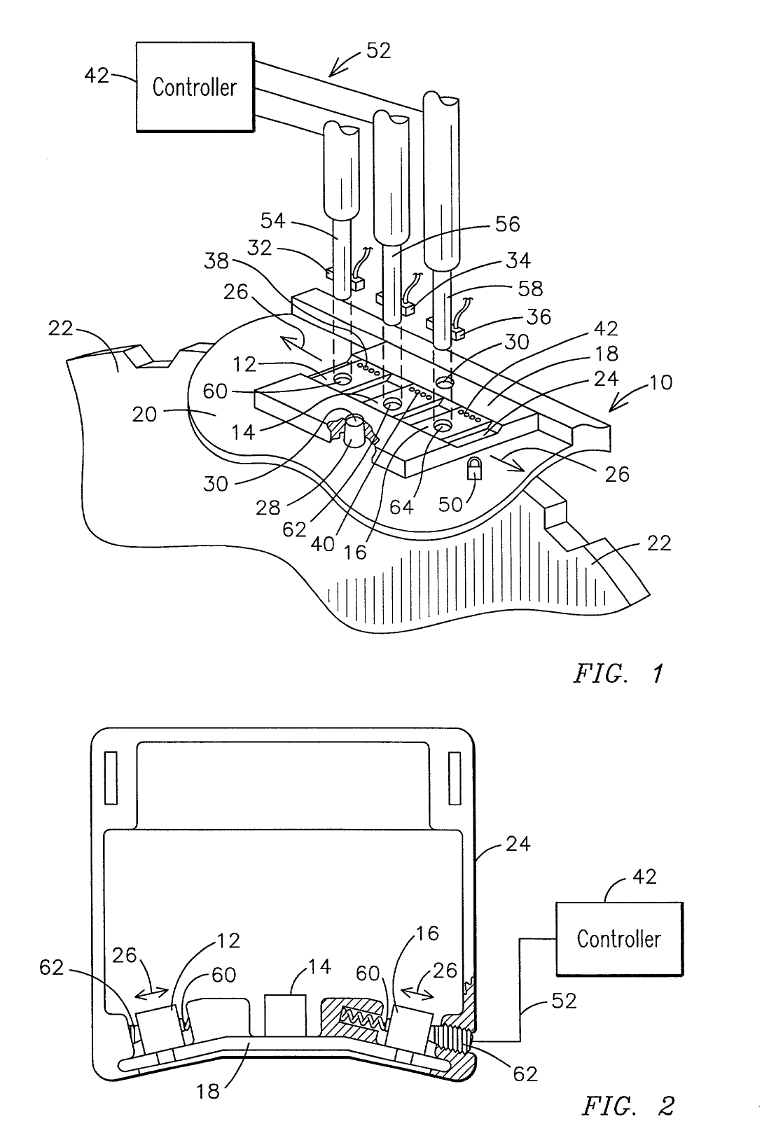

FIG. 1 illustrates one exemplary embodiment of a system for assembling a multisensor device 10 including at least two sensors, such as sensors 12, 14 and 16, mounted on a sensor carrier 18 and operable to provide a respective stream of pulses indicative of angular information of a rotating object, such as the rotor of a dynamoelectric machine (not shown). In one exemplary embodiment, the sensors may comprise Hall or magnetoresistance sensors. It will be understood, however, that the principles of the present invention may be adapted to other types of sensors indicative of angular, linear, translation, or other kinematic information of the moving object. It will be further understood that, although the embodiments of the present invention are illustrated in the context of a multisensor device including three sensors, the present invention is not limited to any specific number of sensors since the number will vary based on the requirements of any given application. As suggested above, it is desirable that the sensors be assembled on the carrier 18 so that the respective streams of pulses have an accurate phasing relationship relative to one another.

As shown in FIG. 1, a registering plate 20 is configured to provide a predefined spatial relationship to the sensor carrier 18 relative to a target wheel 22. As used herein, the expression target wheel refers to an excitation device that, in operation, electromagnetically excites the individual sensors of the multisensor device to reproduce the manner such individual sensors would be excited when installed in a particular type of machine. Thus, the target wheel may be part of a sensor assembly station separate from the machine, or in the event the phasing calibration were to be performed on the machine, it could be the standard toothed wheel part of the machine sensor assembly. It is contemplated that in some applications, e.g., linear applications, the excitation device need not be shaped as a wheel. The registering plate 20 may include registering pins, e.g., tapered pin 28, configured to engage corresponding openings 30 in the sensor carrier. The sensor carrier 18 includes a passageway 24 or compartment for receiving each of the sensors. The passageway allows slidable movement to selected ones of the sensors along a phasing axis 26. That is, the relative position of any individual sensor along the phasing axis determines the respective phasing information of the output signal from that sensor relative to the other sensors in the passageway 24. In one exemplary embodiment, one of the sensors, e.g., the centrally disposed sensor 14, is affixed to the passageway at a predefined location, and the adjusting of the sensor relative positioning comprises adjusting each remaining sensor, e.g., sensors 12 and 16, along the phasing axis until the desired phasing relationship is achieved.

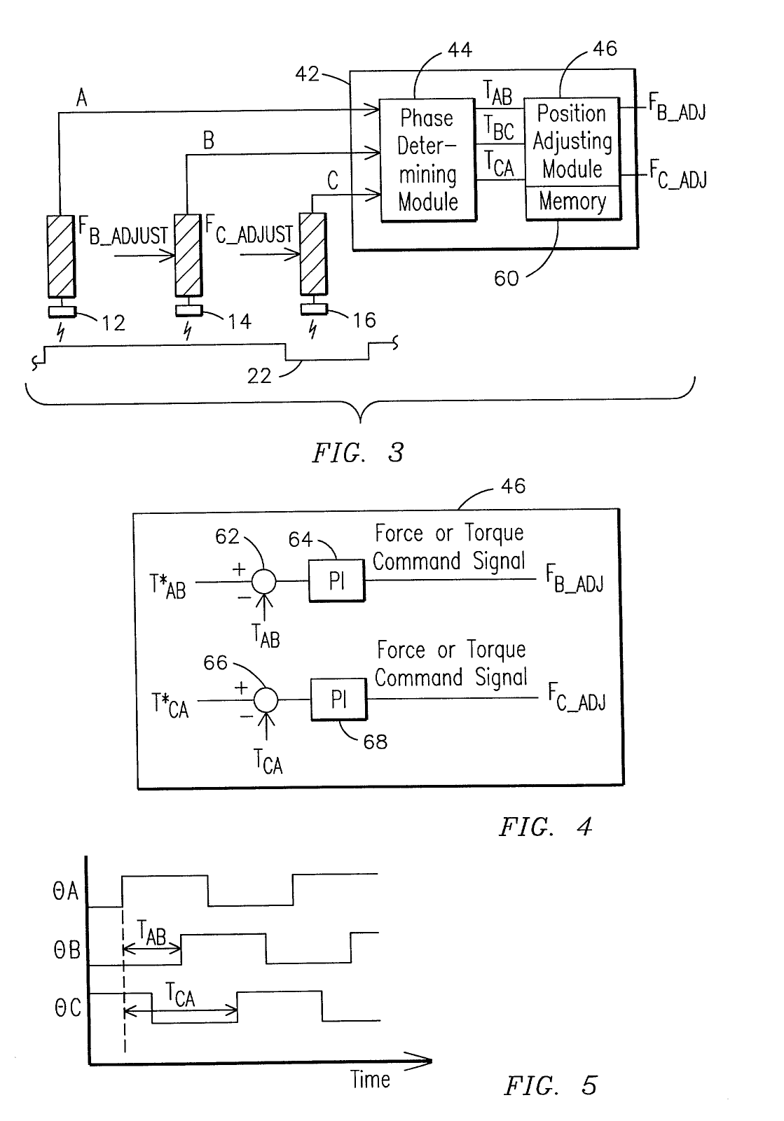

FIG. 1 further illustrates respective modules 32, 34 and 36 for energizing each of the sensors through respective interface contacts 38, 40 and 42 to provide a respective stream of pulses, as relative movement at a generally constant angular rate between the target wheel and the sensor carrier occurs. The assembly system further includes a controller 42, that, as shown in further detail in FIG. 3, includes a phase-determining module 44 configured to determine the phasing relationship of each stream of pulses relative to one another. Based on the determined phasing relationship, a position-adjusting module 46 (FIGS. 3 and 4) is configured to adjust the relative positioning of each selected sensor along the phasing axis until a desired phasing relationship is achieved between the streams of pulses. Once the desired phasing relationship is achieved, a sensor-affixing module, conceptually represented by a lock symbol 50 in FIG. 1, is configured to affix or lock each sensor in the sensor carrier passageway to ensure the respective streams of pulses provided by the at least two sensors maintain the desired phasing relationship. It will be appreciated by those skilled in the art that the sensor-affixing to the sensor carrier may be performed using any well-known affixing technique, such as may be performed using a suitable bonding agent, e.g., epoxy, instant cement, ultraviolet-cured adhesive; or welding technique, e.g., ultrasonic welding; thermal upset, etc. As shown in FIG. 1, the controller includes an actuator 52 independently connectable to each selected sensor through one or more respective locating pins 54, 56, and 58 to drive each selected sensor to respective positions along the phasing axis for achieving the desired phasing relationship. In the embodiment of FIG. 1, each locating pin is connectable to a respective slot 60, 62 and 64 in each selected sensor.

It will be appreciated by those skilled in the art that other embodiments may be used equally effectively to achieve the desired sensor-relative-positioning along the phasing axis. For example, as shown in FIG. 2, the sensor carrier 18 may include a respective biasing device 60, such as a spring or other resilient material, for each selected sensor. In this exemplary embodiment, the actuator may take the form of a jackscrew 62 connectable to each selected sensor opposite the biasing device 60 so that rotation of the jackscrew causes linear movement of the sensor in opposition to the biasing device along the phasing axis 26.

FIG. 3 illustrates in block diagram representation exemplary details regarding controller 42. For example, phase-determining module 44 allows for determining the phasing relationship in the streams of pulses from sensors 12, 14, and 16 by calculating the actual elapsed time or time interval between corresponding transitions in the respective streams of pulses. For example, as shown in FIG. 5, time interval T_{AB} allows for determining the phasing relationship for the streams of pulses labeled θ_{A} and θ_{B}. Similarly, time interval T_{CA} allows for determining the phasing relationship for the streams of pulses labeled θ_{A} and θ_{C}. A target elapsed time or time interval may be stored in a memory 60 for the corresponding transitions or edges. For example, in one exemplary application, the target time interval between the corresponding transitions for each of three sensors should correspond to 120 electrical degrees. The calculated or measured time intervals may be compared to the target time intervals so that appropriate adjustments may be made to the relative positioning of the sensors along the phasing axis.

FIG. 4 illustrates an exemplary embodiment for position-adjusting module 46. This embodiment assumes that one of the sensors serves as a reference, e.g., sensor 12, and that sensor has been located and affixed to the sensor carrier to have a predefined spatial relationship relative to the target wheel. For example, the predefined spatial relationship for the reference sensor 12 may correspond to one of the machine windings. This embodiment further assumes that sensors 14 and 16 will be selectively positioned along the phasing axis to meet the required phasing accuracy. In this embodiment, T*_{AB} represents a signal indicative of a target or commanded time interval that is combined in a subtractor 62 with the calculated time interval T_{AB} to generate an error signal supplied to a suitable position controller 64, e.g., a standard proportional plus integral (PI) controller, to generate a command signal F_{B—}ADJ supplied to actuator 52 (FIG. 1) to generate an appropriate force or torque to position sensor 14 to meet the required phasing relationship between sensors 12 and 14. Similarly, T*_{CA} represents a signal indicative of a target or commanded time interval that is combined in a subtractor 66 with the calculated time interval T_{CA} to generate an error signal supplied to a PI controller 68 to generate a command signal F_{C—}ADJ supplied to actuator 52 to generate an appropriate force or torque to position sensor 16 to meet the required phasing relationship between sensor 12 and 16. It will be appreciated that other position-adjusting schemes may be used to achieve the desired phasing accuracy. For example, in lieu of first affixing one of the sensors and then using that sensor as a reference relative to the other two sensors, one could balance the phasing errors by selectively positioning the three sensors relative to one another until achieving the desired phasing accuracy.

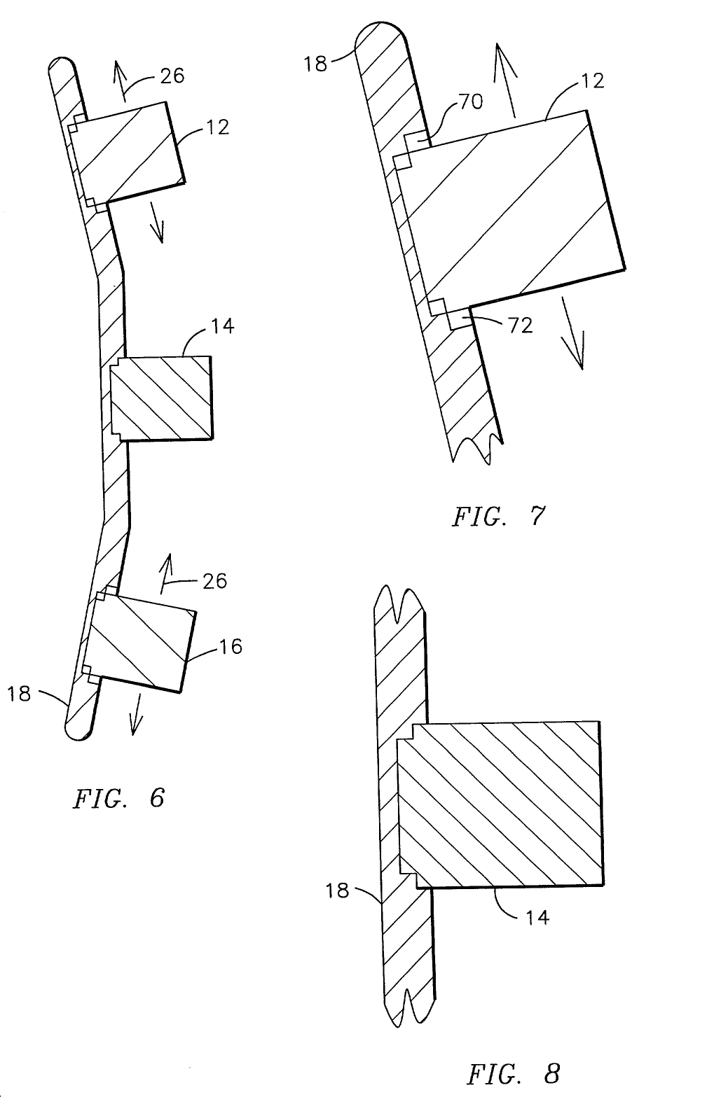

FIGS. 6, 7 and 8 illustrate an exemplary embodiment for sensor carrier 18 that assumes that the centrally-disposed sensor 14 is securely affixed to the sensor carrier 18 while sensors 12 and 16 are allowed to move along their respective phasing axis 26 for appropriate adjustments. As best seen in FIG. 7, sensors 12 and 16 respectively include a pair of keyed detents 70 and 72 that upon appropriate sensor-relative-position adjustment to achieve the required phasing accuracy may be used with any of the above-referred affixing techniques to permanently affix the sensors 12 and 16 to the sensor carrier.

It will be appreciated that aspects of the present invention can be embodied in the form of computer-implemented processes and apparatus for practicing those processes. These aspects of the present invention can also be embodied in the form of computer program code containing computer-readable instructions embodied in tangible media, such as floppy diskettes, CD-ROMs, hard drives, or any other computer-readable storage medium, wherein, when the computer program code is loaded into and executed by a computer, the computer becomes an apparatus for practicing the invention. Aspects of the present invention can also be embodied in the form of computer program code, for example, whether stored in a storage medium, loaded into and/or executed by a computer, or transmitted over some transmission medium, such as over electrical wiring or cabling, through fiber optics, or via electromagnetic radiation, wherein, when the computer program code is loaded into and executed by a computer, the computer becomes an apparatus for practicing the invention. When implemented on a general-purpose computer, the computer program code segments configure the computer to create specific logic circuits or processing modules.

While the preferred embodiments of the present invention have been shown and described herein, it will be obvious that such embodiments are provided by way of example only. Numerous variations, changes and substitutions will occur to those of skill in the art without departing from the invention herein. Accordingly, it is intended that the invention be limited only by the spirit and scope of the appended claims.

What is claimed is:

1. A method for assembling a multisensor device including at least two sensors operable to provide a respective stream of pulses indicative of angular information of a rotating object, the sensors being assembled so that the streams of pulses have an accurate phasing relationship relative to one another, said method comprising:
providing a sensor carrier;
locating the sensor carrier to have a predefined spatial relationship relative to a target wheel, the sensor carrier including a passageway for receiving each of said sensors, the passageway allowing slidable movement to selected ones of said sensors along a phasing axis;
as relative movement between the target wheel and the sensor carrier occurs, energizing each of said sensors to provide a respective stream of pulses;
determining the phasing relationship of each stream of pulses relative to one another;
based on the determined phasing relationship, adjusting the relative positioning of each selected sensor along the phasing axis until a desired phasing relationship is achieved between the stream of pulses;
once the desired phasing relationship is achieved, affixing each sensor in the sensor carrier passageway to ensure the respective streams of pulses provided by the at least two sensors maintain the desired phasing relationship.

2. The method of claim 1 wherein the locating of the sensor carrier comprises providing a registering plate including registering pins configured to engage corresponding openings in the sensor carrier.

3. The method of claim 2 further comprising engaging the registering pins to the corresponding openings in the sensor carrier.

4. The method of claim 1 wherein the determining of the phasing relationship comprises calculating an actual time interval between corresponding transitions in the respective stream of pulses.

5. The method of claim 4 further comprising providing a target time interval for the corresponding transitions.

6. The method of claim 5 wherein the difference between the calculated time interval and the target time interval is processed to generate a command signal supplied to a controller configured to perform the adjusting of the relative positioning of each selected sensor along the phasing axis.

7. The method of claim 6 wherein the controller includes an actuator connectable to each selected sensor to drive each selected sensor to respective positions along the phasing axis for achieving the desired phasing relationship.

8. The method of claim 1 wherein one of the sensors is affixed to the passageway at a predefined location, and the adjusting of sensor-relative-positioning comprises adjusting each remaining sensor along the phasing axis until the desired phasing relationship is achieved.

9. A system for assembling a multisensor device including at least two sensors operable to provide a respective stream of pulses indicative of angular information of a rotating object, the sensors being assembled so that the streams of pulses have an accurate phasing relationship relative to one another, said system comprising:
a sensor carrier;
a registering plate configured to provide a predefined spatial relationship to the sensor carrier relative to a target wheel, the sensor carrier including a passageway for receiving each of said sensors, the passageway allowing slidable movement to selected ones of said sensors along a phasing axis;
a module for energizing each of said sensors to provide a respective stream of pulses, as relative movement between the target wheel and the sensor carrier occurs;
a controller comprising:
a phase-determining module configured to determine the phasing relationship of each stream of pulses relative to one another;
based on the determined phasing relationship, a position-adjusting module configured to adjust the relative positioning of each selected sensor along the phasing axis until a desired phasing relationship is achieved between the streams of pulses; and
once the desired phasing relationship is achieved, a sensor-affixing module configured to affix each sensor in the sensor carrier passageway to ensure the respective stream of pulses provided by the at least two sensors maintain the desired phasing relationship.

10. The system of claim 9 wherein the registering plate includes registering pins configured to engage corresponding openings in the sensor carrier.

11. The system of claim 9 wherein the determining of the phasing relationship comprises calculating a respective time interval between corresponding transitions in the respective stream of pulses.

12. The system of claim 11 further comprising memory including a target time interval for the corresponding transitions.

13. The system of claim 12 wherein the difference between the calculated time interval and the target time interval is processed to generate a command signal for adjusting the relative positioning of each selected sensor.

14. The system of claim 13 wherein the controller includes an actuator connectable to each selected sensor to drive each selected sensor to respective positions along the phasing axis for achieving the desired phasing relationship.

15. The system of claim 14 wherein the actuator comprises at least one locating pin connectable to a respective slot in each selected sensor.

16. The system of claim 15 wherein the sensor carrier includes a respective biasing device for each selected sensor, and the actuator comprises at least one jackscrew connectable to each selected sensor opposite the biasing device so that rotation of the jackscrew causes linear movement of the sensor in opposition to the biasing device and along the phasing axis.

17. The system of claim 9 wherein one of the sensors is affixed to the passageway at a predefined location, and the adjusting of the sensor relative positioning comprises adjusting each remaining sensor along the phasing axis until the desired phasing relationship is achieved.

18. The system of claim 17 wherein the multisensor device comprises three sensors and the one sensor affixed to the passageway at the predefined location is the centrally disposed sensor.

19. The system of claim 9 wherein the multisensor device is selected from the group consisting of a Hall-effect multisensor, and a magneto-resistive multisensor.

20. A method for assembling a multisensor device including at least two sensors operable to provide a respective stream of pulses indicative of kinematic information of a moving object, the sensors being assembled so that the streams of pulses have an accurate phasing relationship relative to one another, said method comprising:
providing a sensor carrier;
locating the sensor carrier to have a predefined spatial relationship relative to an excitation device;
causing movement to selected ones of said sensors along a phasing axis;
as relative movement between the excitation device and the sensor carrier occurs, energizing each of said sensors to provide a respective stream of pulses;
determining the phasing relationship of each stream of pulses relative to one another;
based on the determined phasing relationship, adjusting the relative positioning of each selected sensor along the phasing axis until a desired phasing relationship is achieved between the stream of pulses; and
once the desired phasing relationship is achieved, affixing each sensor in the sensor carrier to ensure the respective streams of pulses provided by the at least two sensors maintain the desired phasing relationship.

21. A system for assembling a multisensor device including at least two sensors operable to provide a respective stream of pulses indicative of kinematic information of a moving object, the sensors being assembled so that the streams of pulses have an accurate phasing relationship relative to one another, said system comprising:
a sensor carrier located to have a predefined spatial relationship relative to an excitation device, the sensor carrier configured to allow movement to selected ones of said sensors along a phasing axis;
a module for energizing each of said sensors to provide a respective stream of pulses, as relative movement between the excitation device and the sensor carrier occurs;
a controller comprising:
a phase-determining module configured to determine the phasing relationship of each stream of pulses relative to one another;
based on the determined phasing relationship, a position-adjusting module configured to adjust the relative positioning of each selected sensor along the phasing axis until a desired phasing relationship is achieved between the streams of pulses; and
once the desired phasing relationship is achieved, a sensor-affixing module configured to affix each sensor to the sensor carrier to ensure the respective stream of pulses provided by the at least two sensors maintain the desired phasing relationship.
